(19) United States
(12) Patent Application Publication
(10) Pub. No.: US 2008/0111462 A1
(43) Pub. Date: May 15, 2008

(54) ORGANIC ELECTRO-LUMINESCENT DISPLAY AND METHOD OF MANUFACTURING THE SAME

(75) Inventors: Ki-deok BAE, Yongin-si (KR); Chan-bong JUN, Yongin-si (KR); Chang-seung LEE, Yongin-si (KR); Hong-shik SHIM, Yongin-si (KR)

Correspondence Address: CANTOR COLBURN, LLP, 20 Church Street, 22nd Floor, Hartford, CT, 06103, US

(73) Assignee: SAMSUNG ELECTRONICS CO., LTD., Suwon-si (KR)

(21) Appl. No.: 11/780,106

(22) Filed: Jul. 19, 2007

(30) Foreign Application Priority Data
Nov. 10, 2006 (KR) 10-2006-0110779

(51) Int. Cl. H01J 1/62; H01J 9/02; H01L 51/54; H01L 51/56

(52) U.S. Cl. 313/494; 427/64

(57) ABSTRACT

An organic electro-luminescent display (“OELD”) and a method of manufacturing the OELD include: a substrate; a plurality of anodes substantially parallel with one another in a first direction and disposed on the substrate; a plurality of cathodes disposed substantially parallel with one another in a second direction orthogonal to the first direction; organic electro-luminescent parts disposed at intersections between the anodes and the cathodes; a plurality of cathode separators each disposed between the cathodes; and gaps separating lower edges of the cathode separators facing the cathodes from the substrate.

This application claims priority to Korean Patent Application No. 10-2006-0110779, filed on Nov. 10, 2006, and all the benefits accruing therefrom under 35 U.S.C. § 119, the contents of which in its entirety are herein incorporated by reference.

### BACKGROUND OF THE INVENTION

1. Field of the Invention

The present invention relates to an organic electro-luminescent display (“OELD”) and a method of manufacturing the same, and more particularly, to a cathode separator of an OELD and a method of manufacturing the same.

2. Description of the Related Art

U.S. Pat. Pub. No. 2005/00116629 to Takamura et al. (hereinafter “Takamura”) discloses a passive matrix type organic electro-luminescent display (“OELD”) using a cathode separator. The cathode separator separates adjacent cathodes from each other and prevents a short-circuit between the adjacent cathodes.

In manufacturing the cathodes, as in Takamura, the cathode separator is formed first, and then a cathode material is deposited on the cathode separator. The cathode separator is generally patterned using a photolithography method using photoresist. The cathode separator has a cross-sectional profile that is narrower at a bottom surface thereof (e.g., the surface disposed on the anode separator in Takamura) than a top surface of the cathode separator, thus providing a cathode separator cross-section that is inverse trapezoidal in shape. Because the opposing sides of the cathode separator slope inwardly with respect to a substrate on which it is disposed, formation of a cathode material on either of the opposing sides of the cathode separator is discouraged. As a result, the cathode material is separated into strips. Even still, cathode material can form on the sides of the cathode separator.

Accordingly, the successful separation of cathodes is required to preclude short-circuits between adjacent cathodes. If cathode material contacts the sides of the cathode separators, short-circuits between cathodes can result, degrading OELD performance. Therefore, successful manufacture of passive matrix type OLED devices is dependent on discouraging formation of cathode material on the sides of the cathode separators. If the cathode separator is not successfully formed, defective cathodes reduce a production yield of the OLEDs, thus increasing a manufacturing cost of the OLEDs.

### BRIEF SUMMARY OF THE INVENTION

The present invention provides an organic electro-luminescent display (“OELD”) and a method of manufacturing the OELD having a separator which is easily manufactured and has a substantially reduced defective rate of cathodes manufactured using the separator.

According to an exemplary embodiment of the present invention, provided is an OELD including a substrate; a plurality of anodes disposed on the substrate substantially parallel with one another in a first direction; a plurality of cathodes disposed substantially parallel with one another in a second direction orthogonal to the first direction; organic electro-luminescent parts disposed at intersections between the anodes and the cathodes; a plurality of cathode separators each disposed between the cathodes, each of the cathode separators having an upper portion and a lower portion; and gaps formed at both sides of each of the cathode separators separating lower edges of the cathode separators facing the cathodes from the substrate.

According to another exemplary embodiment of the present invention, provided is a method of manufacturing an OELD. The method includes disposing a plurality of anodes on a substrate substantially parallel with one another in a first direction, disposing a plurality of cathodes substantially parallel with one another in strip shapes in a second direction orthogonal to the first direction; forming a plurality of cathode separators each between the cathodes to insulate adjacent cathodes from each other; and depositing a cathode material on the substrate to form the cathodes separated from one another by the cathode separators between the cathode separators, wherein the formation of the cathode separators includes forming the cathode separators on the substrate and then forming gaps separating lower edges of sides of the cathode separators facing the cathodes from the substrate.

The formation of the gaps may include heating and cooling the substrate to deform and restore the substrate on which the cathode separators are formed in order to lift the lower edges of the cathode separators from the substrate.

Heat may be differentially applied to a surface of the substrate on which the cathode separators are formed and an opposite surface to deform the substrate.

Heating and cooling of the substrate may be simultaneously performed, wherein the heating is performed above an upper surface of the substrate on which the cathode separators are formed, and the cooling is performed under a lower surface of the substrate.

Heating and cooling of the substrate may be sequentially performed, wherein the heating is performed with respect to an entire portion of the substrate, and the cooling is performed with respect to a lower surface of the substrate on which the cathode separators are not formed.

### BRIEF DESCRIPTION OF THE DRAWINGS

The above and other aspects, features and advantages of the present invention will become more apparent by describing in further detail exemplary embodiments thereof with reference to the attached drawings, wherein like elements are numbered alike, in which:

FIG. 1 is a schematic partial plan view illustrating a layout of an organic electro-luminescent display (“OELD”) according to an exemplary embodiment of the present invention;

FIG. 2 is a schematic partial perspective view of the OELD of FIG. 1;

FIG. 3 is a partial enlarged cross-sectional view of a portion of a cathode separator adopted in an OELD according to an exemplary embodiment of the present invention;

FIGS. 4A through 4H are partial cross-sectional views illustrating a method of manufacturing an OELD according to an exemplary embodiment of the present invention;

FIG. 5A is a scanning electron microscope (“SEM”) image of a cathode separator lifting from a substrate;

FIG. 5B is an SEM image of the cathode separator on which a cathode material is deposited; and

FIGS. 6A and 6B are partial cross-sectional views illustrating a method of manufacturing an OELD according to another exemplary embodiment of the present invention.

### DETAILED DESCRIPTION OF THE INVENTION

The present invention will now be described in greater detail with reference to the accompanying drawings.

It will be understood that when an element is referred to as being “on” another element, it can be directly on the other element or intervening elements may be present therebetween. In contrast, when an element is referred to as being “disposed on” or “formed on” another element, the elements are understood to be in at least partial contact with each other, unless otherwise specified.

The terminology used herein is for the purpose of describing particular embodiments only and is not intended to be limiting of the invention. As used herein, the singular forms “a”, “an” and “the” are intended to include the plural forms as well, unless the context clearly indicates otherwise. The use of the terms “first”, “second”, and the like do not imply any particular order but is included to identify individual elements. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In the drawings, like reference numerals in the drawings denote like elements and the thicknesses of layers and regions are exaggerated for clarity.

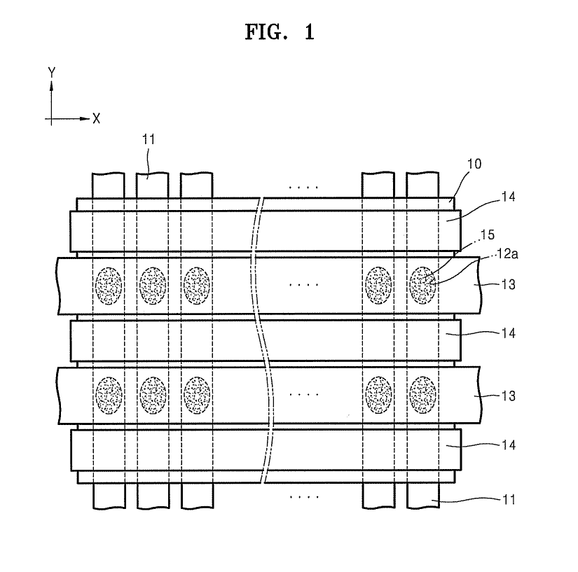

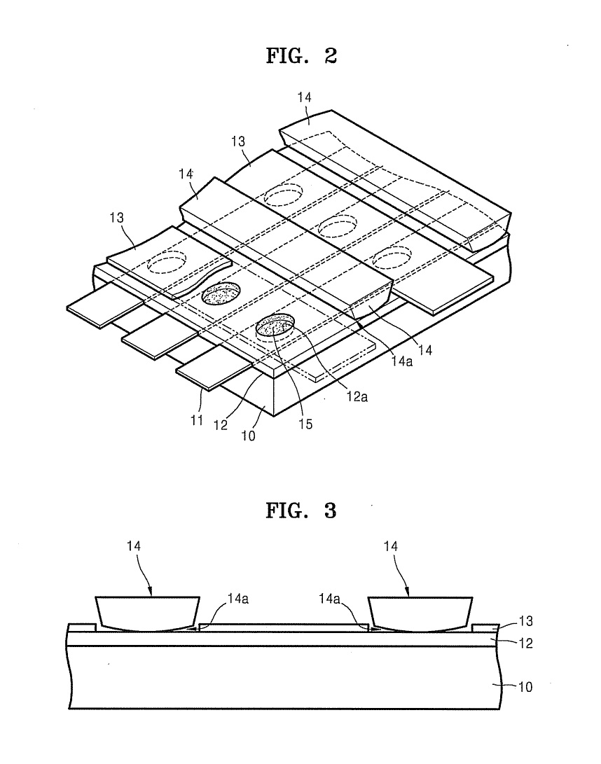

FIG. 1 is a schematic partial plan view illustrating a layout of an organic electro-luminescent display (“OELD”) according to an exemplary embodiment of the present invention. FIG. 2 is a schematic partial perspective view of the OELD of FIG. 1.

Referring to FIGS. 1 and 2, a plurality of anodes 11 are formed on a substrate 10, in a first direction, i.e., the y direction in FIG. 1, to be substantially parallel with one another. An insulating layer 12 is formed on the anodes 11. The substrate 10 is formed of a transparent, substantially firm plate part, e.g., a glass substrate or a plastic substrate. The anodes 11 are formed of a transparent conductor, e.g., ITO. The insulating layer 12 may be formed of a photosensitive material, e.g., polyimide, polyacryl, polymer, etc. using a photolithography method to insulate the anodes 11 from cathodes 13 which will be described further below.

A plurality of cathodes 13 are formed on the insulating layer 12, in a second direction orthogonal to the first direction, i.e., the x direction in FIG. 1, substantially parallel with one another. Windows 12a are formed in the insulating layer 12, which insulates the anodes 11 from the cathodes 13. The windows 12a are formed at intersections between the anodes 11 and the cathodes 13. The windows 12a are filled with an organic electro-luminescent material 15. An organic electro-luminescent material may fill the windows 12a entirely, and an edge of the organic electro-luminescent material may overlap with edges of the windows 12a. As shown in FIGS. 1 and 2, the windows 12a may be ellipsoidal, for example, but is not limited thereto. Alternatively, the windows 12a may be rectangular.

Cathode separators 14, each having a predetermined width, are provided between the cathodes 13 to extend in the same direction as the cathodes 13. Negative photoresist having a width between about 20 μm and about 30 μm, such as polyimide, polyacryl, polymer, or the like, is coated and then patterned into strip shapes having an inverse-trapezoidal cross-section extending to a predetermined height using a photolithography method. The cathode separators 14 are defined each having an upper portion and a lower portion The cathode separators 14 extend higher than other elements, and the upper portions of the cathode separators 14, which absorb a relatively large amount of ultraviolet rays during exposure, are wider than the lower portions of the cathode separators 14. As shown in FIG. 3, gaps 14a are formed at both sides of each of the lower portions of the cathode separators 14, and thus both sides of the lower portion are spaced apart from the substrate 10 due to the gaps 14a. If the cathode separators 14 are spaced apart from the substrate 10 due to the gaps 14a as described above, a deposited material on the upper portion is fully separated from the sides of the cathode separators 14. Thus, the cathodes 13 formed between the cathode separators 14 are completely separated from adjacent cathodes 13.

The gaps 14a are characteristic elements of the OELD of the present invention and contribute to completely insulate a deposited material formed on respective cathode separators 14 from a deposited material formed on the other cathode separators 14 when a cathode material is deposited. As a result, the cathodes 13 are formed to be completely electrically insulated from one other. Sides of the cathode separators 14 at the lower portion do not form an inwardly sloping angle with respect to the substrate 10 due to the gaps 14a. Although the cathode separators 14 form an inwardly sloping angle with respect to the substrate 10, a cathode material is not deposited in the gaps 14a. Thus, the gaps 14a allow the cathodes 13 to be completely separated from one another. The gaps 14a are further described below in the description of a method of manufacturing an OELD according to the present invention.

A method of manufacturing an OELD according to another exemplary embodiment of the present invention will now be schematically described.

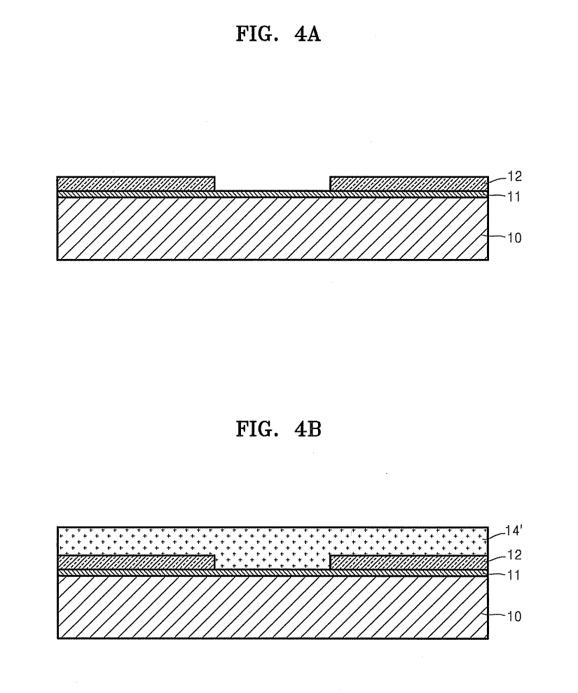

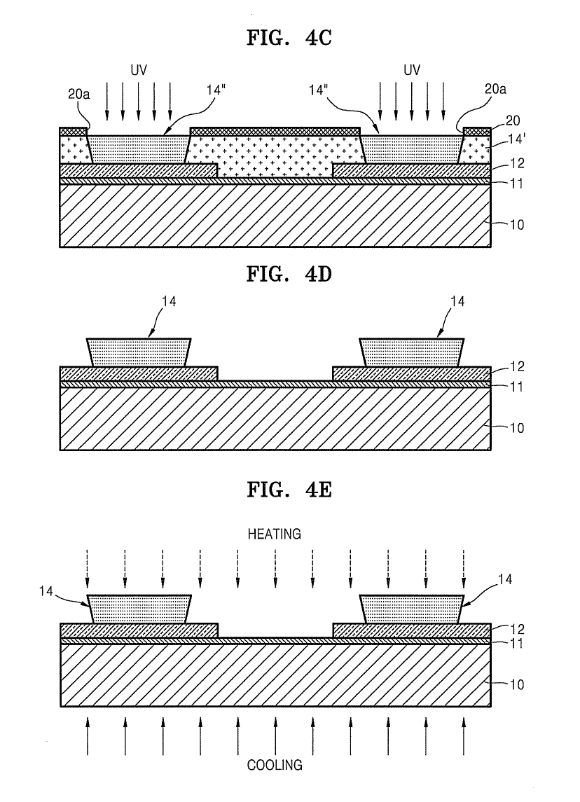

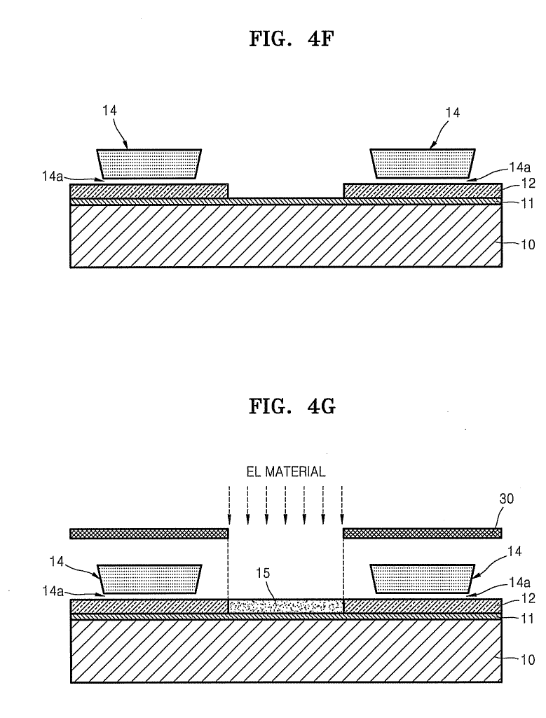

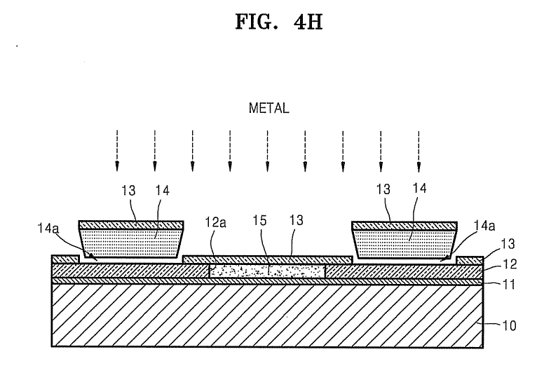

Referring to FIG. 4A, an anode 11 having a strip shape is formed on a substrate 10, and an insulating layer 12 having a window 12a is formed on the anode 11. The anode 11 is obtained by depositing and patterning of ITO. The insulating layer 12 is formed of a photosensitive material. The window 12a is an area formed in the insulating layer 12 and formed using a photolithography method. The windows 12a are then filled with an organic electro-luminescent material.

As shown in FIG. 4B, a negative photoresist such as polyimide (“PI”), polyacryl (“PA”), polymer, or the like is coated on the insulating layer 12 to a predetermined thickness to form a separator material 14′.

As shown in FIG. 4C, the separator material 14′ is exposed to ultraviolet rays using a mask 20 having openings 20a with a predetermined width. A lower portion of the separator material 14′ absorbs less light energy than an upper portion of the separator material 14′. Thus, exposure areas 14″ are formed through the absorption of light so that the upper portions of the exposure areas 14″ are wide, and lower portions are narrow.

As shown in FIG. 4D, the separator material 14′ is developed to obtain cathode separators 14. The cathode separators 14 have inverse trapezoidal shapes as described above so that upper areas of the cathode separators 14 are wider than lower areas of the cathode separators 14 due to a difference in energy absorption which occurs during exposure.

As shown in FIG. 4E, a lower portion of the substrate 10 is cooled, and an upper portion of the substrate 10, i.e., a portion in which the cathode separators 14 are formed, is heated. Heat is differentially applied so that a temperature of the upper portion of the substrate 10 in which the cathode separators 14 are formed is higher than that of the opposite lower portion of the substrate 10. The substrate 10 is bent or curved due to differential heating or simultaneous heating and cooling to extend in a direction along which the cathode separators 14 are formed. However, the opposite lower portion to the bent portion of the substrate 10 shrinks and thus is bent as a bow to be convex upward. If the substrate 10 is bent as described above, the cathode separators 14 formed on the convex portion of the substrate 10 also extend in the direction along which the cathode separators 14 are formed. If the entire portion of the substrate 10 is cooled after the above-described process, the substrate 10 is restored to its original state, and the cathode separators 14 thermoset during heating and thus are not restored to their original widths. Thus, gaps 14a are formed among the cathode separators 14 which are not restored to their original states when the substrate 10 is restored to its original state. Therefore, as shown in FIG. 4F, the cathode separators 14 lift from the substrate 10. Heights of the gaps 14a are within a range between about 100 Å and about 8000 Å. The gaps 14a may be wholly formed under the cathode separators 14, as shown in FIG. 4E, or may be formed only beside both edges of the lower portions of the cathode separators 14, as shown in FIG. 3.

As shown in FIG. 4F, the cathode separators 14 lift from the substrate, and more specifically, from the insulating layer 12, and the gaps 14a are formed between the cathode separators 14 and the insulating layer 12 or the substrate 10. The cathode separators 14 are completely separated from the substrate in FIG. 4. However, portions of the cathode separators 14 may contact the substrate 10 as shown in FIG. 3. Also, the cathode separators 14 may be connected to one another through interlink bridges in an outer area of an image display area of the OELD and fixed to the substrate 10 through the interlink bridges. Thus, the cathode separators 14 are completely separated from the substrate 10 in the image display area but are fixed to the substrate 10 through the interlink bridges provided outside of the image display area.

As shown in FIG. 4G, an organic electro-luminescent material 15 is formed in a window 12a of the insulating layer 12 employing a selective vapor deposition method using a pattern mask 30.

As shown in FIG. 4H, a metal is deposited on the substrate 100 to form cathodes 13 having a thickness between about 100 Å and about 10,000 Å above the insulating layer 12. The metal is deposited on the insulating layer 12 and the cathode separators 14. Here, edges of lower portions of the cathode separators 14 are separated from the substrate 10 or the insulating layer 12 due to the gaps 14a, and a material deposited on the insulating layer 12 is completely insulated from the material deposited on the cathode separators 14. Thus, a plurality of cathodes 13 can be obtained substantially parallel with one another and completely electrically separated from one another.

A desired passive matrix type OELD may be obtained through a general subsequent process after the above-described processes.

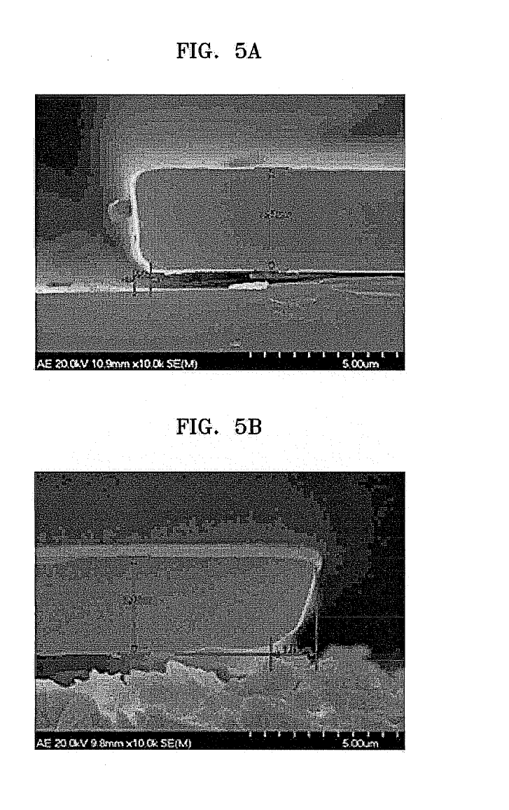

FIG. 5A is a scanning electron microscope (“SEM”) image of the cathode separators 14 separated from the substrate 10 through the process described with reference to FIG. 4E. FIG. 5B is an SEM image of a cathode material deposited on the substrate 10 on which the cathode separators 14 are formed. As shown in FIG. 5A, cathode separators are separated from a substrate, and gaps are formed between the cathode separators and the substrate. As shown in FIG. 5B, when a cathode material is deposited, the cathode material is not directly deposited on sides of the cathode separators. Although the cathode material may be indirectly deposited on the inwardly sloping sides of the separators, the gaps provide an area in which the cathode material cannot be deposited. The gaps do not allow the cathode material formed on the cathode separators to electrically contact cathodes formed between the cathode separators.

According to exemplary embodiments of the present invention, the method of forming the gaps 14a under the separators 14 may be variously modified.

Heating and cooling are simultaneously performed in FIG. 4E. Here, cooling may be performed using a unit capable of taking heat from a lower surface of a substrate. For example, if the substrate is placed on a metal base having high conductivity, and then heat is applied above the substrate, an upper portion of the substrate is heated, and a lower portion of the substrate is deprived of heat due to its contact with the metal base and thus cooled.

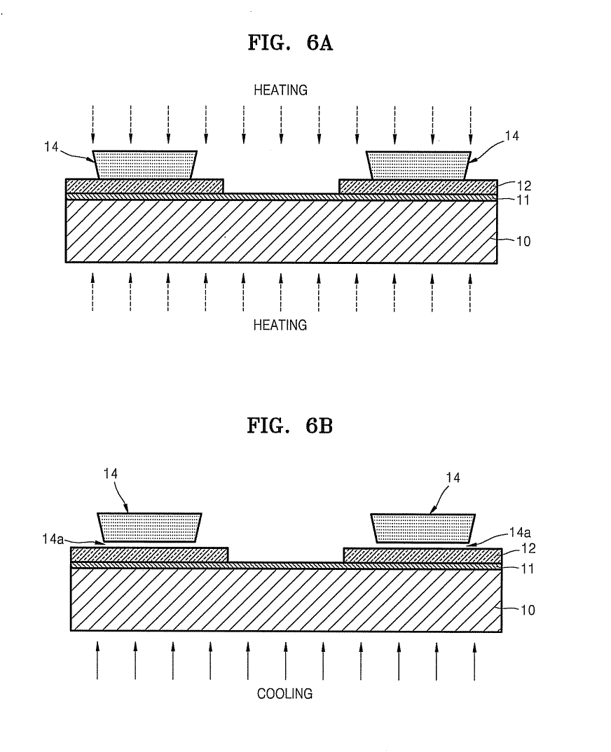

As shown in FIG. 6A, upper and lower surfaces of a substrate 10 are heated. As shown in FIG. 6B, the lower surface of the substrate 10 is cooled. Thus, the lower surface of the substrate 10 on which cathode separators 14 are formed is deformed to be convex upward. If the entire portion of the substrate 10 is cooled, the substrate 10 is restored to its original state, but the cathode separators 14 thermoset during heating, and thus are not restored to their original states. Thus, the cathode separators 14 lift from the substrate 10.

As described above, the present invention is characterized by structures of cathode separators and a method of forming the cathode separators. In other words, gaps are formed under the cathode separators in terms of the structures of the cathode separators. In terms of the method, the cathode separators lift from a substrate or an insulating layer to form the gaps, and cathodes formed between the cathode separators are completely separated from one another due to the gaps.

As described above, in an OELD and a method of manufacturing the OELD according to the present invention, gaps can be formed under cathode separators to successfully form cathodes. Sides of the cathode separators do not slope inwardly with respect to a substrate, and the cathodes can be stably and complete separated from one another regardless of cross-sections of the cathode separators due to the gaps.

The present invention can be applied to a passive matrix type OELD including a plurality of cathodes, which are formed substantially parallel with one another due to cathode separators, and a method of manufacturing the passive matrix type OELD

While the present invention has been particularly shown and described with reference to exemplary embodiments thereof, it will be understood by those of ordinary skill in the art that various changes in form and details may be made therein without departing from the spirit and scope of the present invention as defined by the following claims. In addition, many modifications may be made to adapt particular circumstances or materials to the teachings of the invention without departing from the essential scope thereof. Therefore, it is intended that the invention not be limited to the particular exemplary embodiments disclosed as the best mode contemplated for carrying out the invention, but that the invention will include all embodiments falling within the scope of the appended claims.

What is claimed is:

1. An organic electro-luminescent display comprising:
a substrate;
a plurality of anodes disposed on the substrate substantially parallel with one another in a first direction;
a plurality of cathodes disposed substantially parallel with one another in a second direction orthogonal to the first direction;
organic electro-luminescent parts each disposed at intersections between the anodes and the cathodes;
a plurality of cathode separators each disposed between the cathodes, each of the cathode separators having an upper portion and a lower portion; and
gaps separating lower edges of the cathode separators facing the cathodes from the substrate.

2. The organic electro-luminescent display of claim 1, wherein the gaps completely separate the lower portion of the cathode separators from the substrate in an image display area of the organic electro-luminescent display.

3. The organic electro-luminescent display of claim 1, wherein the gaps partially separate the cathode separators from the substrate in an image display area of the organic electro-luminescent display.

4. The organic electro-luminescent display of claim 3, wherein the gaps partially separate the cathode separators from the substrate only at opposing outboard ends defining the lower portion of the cathode separators.

5. The organic electro-luminescent display of claim 3, wherein only a middle portion of the lower portion of the cathode separators contact the substrate.

6. The organic electro-luminescent display of claim 1, further comprising an insulating layer disposed on the anodes, the insulating layer having a plurality of windows disposed at the intersections of the cathodes and anodes.

7. The organic electro-luminescent display of claim 6, wherein the organic electro-luminescent material is disposed within each of the windows.

8. The organic electro-luminescent display of claim 1, wherein each of the cathode separators have a first side and a second side and at least one of the first and second sides inclines inwardly towards the substrate.

9. The organic electro-luminescent display of claim 1, wherein each of the gaps is between about 100 Å and about 8,000 Å.

10. The organic electro-luminescent display of claim 2, wherein each of the gaps is between about 100 Å and about 8,000 Å.

11. The organic electro-luminescent display of claim 3, wherein each of the gaps is between about 100 Å and about 8,000 Å.

12. A method of manufacturing an organic electro-luminescent display, the method comprising:
disposing a plurality of anodes on a substrate substantially parallel with one another in a first direction;
disposing a plurality of cathodes substantially parallel with one another in strip shapes in a second direction orthogonal to the first direction;
forming a plurality of cathode separators each between the cathodes to insulate adjacent cathodes from each other; and
depositing a cathode material on the substrate to form the cathodes separated from one another by the cathode separators between the cathode separators,
wherein the forming the cathode separators comprises forming the cathode separators on the substrate and then forming gaps separating lower edges of sides of the cathode separators facing the cathodes from the substrate.

13. The method of claim 12, wherein the forming the gaps comprises heating and cooling the substrate to deform and restore the substrate on which the cathode separators are formed to lift the lower edges of the cathode separators from the substrate.

14. The method of claim 13, wherein heat is differentially applied to a surface of the substrate on which the cathode separators are disposed and an opposite surface to deform the substrate.

15. The method of claim 12, wherein the gaps are between about 100 Å and about 8,000 Å.

16. The method of claim 12, wherein thicknesses of the cathodes are adjusted within a range between about 100 Åand about 10,000 Å.

17. The method of claim 13, wherein the heating and cooling of the substrate are simultaneously performed, wherein the heating is performed above an upper surface of the substrate on which the cathode separators are formed, and the cooling is performed under a lower surface of the substrate.

18. The method of claim 13, wherein the heating and cooling of the substrate are sequentially performed, wherein the heating is performed with respect to an entire portion of the substrate, and the cooling is performed with respect to a lower surface of the substrate on which the cathode separators are not formed.
